(19) United States
(12) Patent Application Publication
(10) Pub. No.: US 2019/0073010 A1
(43) Pub. Date: Mar. 7, 2019

(54) DETERMINE COMPUTING DEVICE INFORMATION

(71) Applicant: Hewlett Packard Enterprise Development LP, Houston, TX (US)

(72) Inventors: Daniel Humphrey, Cypress, TX (US); Apollo Fong, Houston, TX (US); David P. Mohr, Houston, TX (US)

(21) Appl. No.: 15/697,063

(22) Filed: Sep. 6, 2017

Related U.S. Application Data
(63) Continuation of application No. 15/696,857, filed on Sep. 6, 2017.

(51) Int. Cl. G06F 1/26; G06F 11/30; H05K 7/14; G06F 1/18

(52) U.S. Cl. CPC G06F 1/266; G06F 11/30; H04Q 2209/60; G06F 1/18; H04Q 2209/823; H05K 7/1498

(57) ABSTRACT

Example implementations relate to determining computing device information. In some examples, a controller may comprise a processing resource and a memory resource storing machine-readable instructions to request a handshake signal from a power supply of a computing device, receive a response signal from the power supply that includes modified power factor correction characteristics in response to the handshake signal request, and determine, based on the modified power factor correction characteristics, information about the computing device.

### BACKGROUND

A power distribution unit (PDU) can distribute electric power to computing devices. For example, computing devices included in a data center can receive electric power via a PDU.

A PDU can communicate with computing devices the PDU is providing power to. For example, the PDU may communicate with the computing devices for management purposes.

### BRIEF DESCRIPTION OF THE DRAWINGS

FIG. 1 illustrates an example of a system consistent with the disclosure.

FIG. 2A illustrates an example of a modified waveform consistent with the disclosure.

FIG. 2B illustrates an example of a modified waveform consistent with the disclosure.

FIG. 2C illustrates an example of a modified waveform consistent with the disclosure.

FIG. 3 is a diagram of an example controller to determine computing device information consistent with the disclosure.

FIG. 4 is a block diagram of an example of a system consistent with the disclosure.

FIG. 5 illustrates an example of a method consistent with the disclosure.

FIG. 6 is a diagram of an example controller to determine computing device information consistent with the disclosure.

FIG. 7 is a block diagram of an example of a system consistent with the disclosure.

FIG. 8 illustrates an example of a method consistent with the disclosure.

### DETAILED DESCRIPTION

A PDU may communicate with a power supply of a computing device. As used herein, the term “power distribution unit” (PDU) can, for example, refer to a device to distribute electric power. The PDU can distribute electric power to a computing device. As used herein, the term “computing device” can, for example, refer to a laptop computer, a desktop computer, a server, or networking equipment, among other types of computing devices. As used herein, the term “power supply” can, for example, refer to a device that can supply electric energy to an electrical load.

For example, a server can include two power supplies. The PDU can distribute electric power to each of the two power supplies of the server such that the server can operate to perform computing functions.

A PDU can communicate with a power supply of a computing device. For example, a PDU may communicate with a power supply via a serial bus or other power line communication. In some examples, the PDU can communicate with the power supply via modulation of an input voltage of the power supply. However, communication via the serial bus or by modulating an input voltage of the power supply may include line cords and connectors between the PDU and the power supply that may be cost and/or space prohibitive.

In some implementations, determining computing device information can allow for communication between a PDU and a power supply of a computing device while accounting for cost and/or space considerations. For example, utilizing this particular communication mechanism can prevent the use of cost and/or size prohibitive line cords and/or connectors between the PDU and the power supply. As used herein, the term “mechanism” can, for example, refer to a component of a system or device to serve a plurality of functions, including but not limited to, software components, electronic components, electrical components, mechanical components, electro-mechanical components, etc.

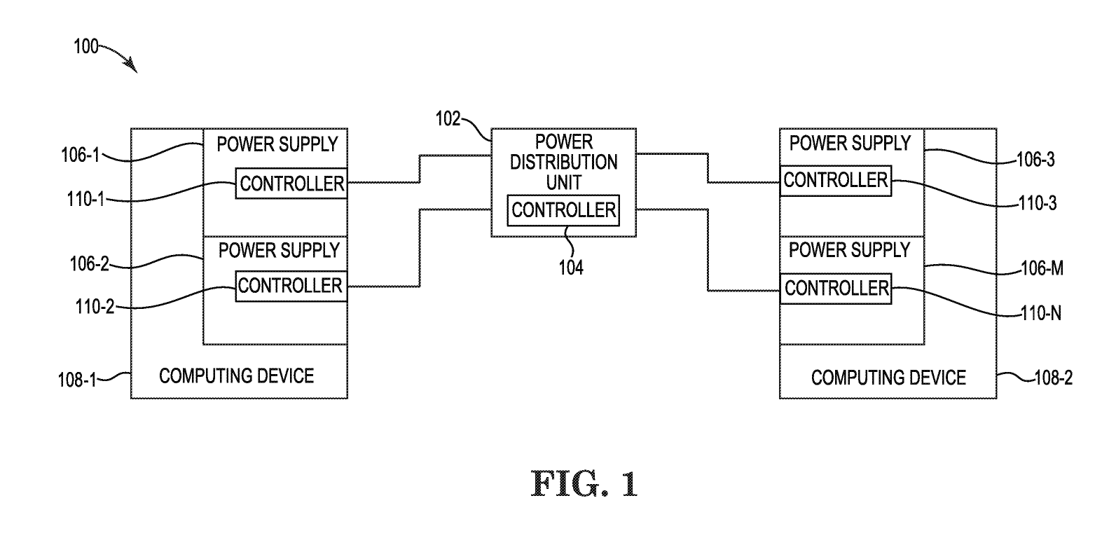

FIG. 1 illustrates an example of a system 100 consistent with the disclosure. As illustrated in FIG. 1, the system 100 may include a PDU 102, controller 104 of the PDU 102, and computing devices 108-1, 108-2. Computing device 108-1 can include power supplies 106-1, 106-2 and controllers 110-1, 110-2. Computing device 108-2 can include power supplies 106-3, 106-M and controllers 110-3, 110-N. Power supplies 106-1, 106-2, 106-3, 106-M can be referred to collectively as power supply 106. Computing devices 108-1, 108-2 can be referred to collectively as computing device 108.

Controller 104 can be included in a PDU 102. For example, PDU 102 can include controller 104 to perform functions related to determining computing device information. Although controller 104 is illustrated in FIG. 1 as being included in PDU 102, examples of the disclosure are not so limited. For example, controller 104 can be located remote from PDU 102.

Controller 104 can receive a waveform corresponding to an input current that can include a non-cyclical irregular waveform modification from a power supply 106 of a computing device 108. As used herein, the term “waveform” can, for example, refer to a shape and form of a signal such as a wave. As used herein, the term “wave” can, for example, refer to a curve representing periodic oscillations of amplitude. For example, the signal can be a sinusoidal waveform. As used herein, the term “sinusoidal waveform” can, for example, refer to a curve representing periodic oscillations of constant amplitude as given by a sine function.

A power supply 106 of a computing device 108 can generate an input current. As used herein, the term “current” can, for example, refer to a flow of electric charge. For example, the power supply 106 can generate an input current for computing device 108. The input current consumed by power supply 106 can be supplied to computing device 108 after conversion.

Computing device 108 can, in some examples, be a server. As used herein, the term “server” can, for example, refer to an electronic device that provides functionality for programs or other devices, such as sharing data or resources, or performing computations. However, examples of the disclosure are not limited to computing device 108 being a server.

The non-cyclical irregular waveform modification can be generated by a controller 110 included in the power supply 106. The controller 110 of power supply 106 can be a power factor correction controller. As used herein, the term “power factor” can, for example, refer to a ratio between the real power flowing to a load and the apparent power in a circuit. The power factor correction controller 110 can modify an input current to power supply 106 of computing device 108 to generate various power factor levels for computing device 108.

The power factor controller 110 can modify the input current to include the non-cyclical irregular waveform. As used herein, the phrase “non-cyclical irregular” can, for example, refer to an absence of a regular recurrence. In other words, the non-cyclical irregular waveform can be a waveform that, for a cycle of the waveform, includes a curve that is a deviation from a cyclical waveform. As used herein, the term “cycle” can, for example, refer to an event in which a waveform starts with a rise from a zero level to a maximum amplitude, its return to the zero level, its fall to a minimum level (e.g., in the opposite direction of the maximum level), and its return to the zero level in a given interval. As an example, a sine wave can complete a cycle in an interval from 0 to 27 radians.

The non-cyclical irregular waveform modification can include an intra-cycle waveform modification in the waveform corresponding to the input current of computing device 108. As used herein, the term “intra-cycle” can, for example, describe an occurrence within one cycle of a waveform. For example, the controller 110 of the power supply 106 of computing device 108 can generate a waveform with a modification located within one cycle of the waveform, where the modification includes a curve with a deviation from the cyclical waveform.

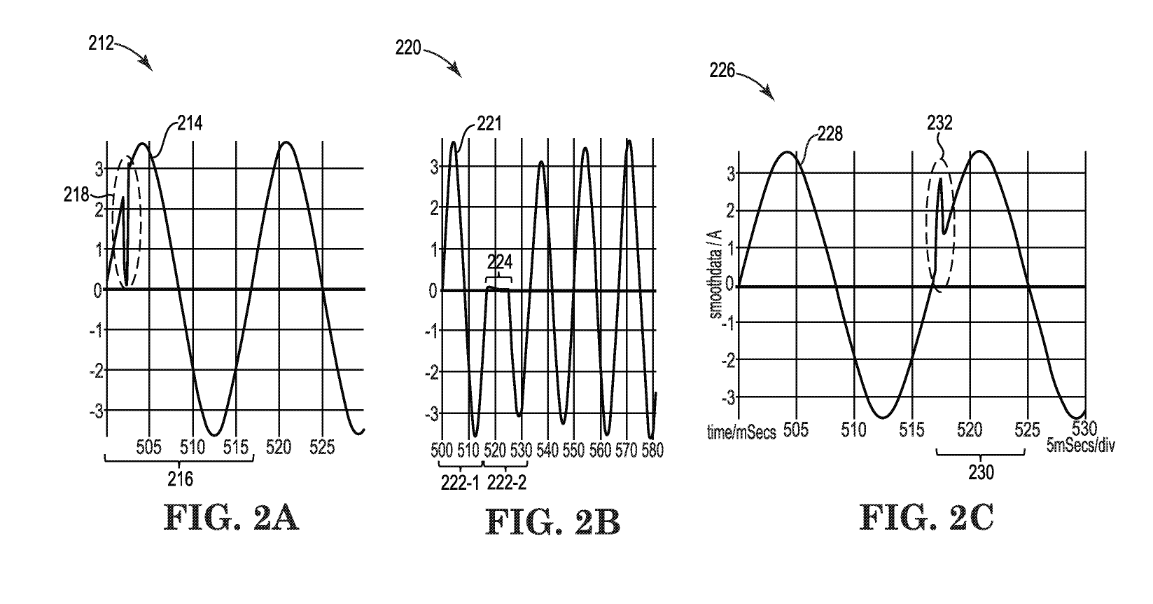

In some examples, the non-cyclical irregular waveform modification can include a notch in the waveform corresponding to the input current. As used herein, the term “notch” can, for example, refer to an angular indentation. For example, the curve of a half cycle of the waveform corresponding to the input current can include a notch, as is further described in connection with FIG. 2A.

In some examples, the non-cyclical irregular waveform modification can include a skipped half-cycle in the waveform corresponding to the input current. As used herein, the term “half-cycle” can, for example, refer to one half of the cycle of a waveform. For example, a half cycle of the waveform corresponding to the input current can be skipped, as is further described in connection with FIG. 2B.

In some examples, the non-cyclical irregular waveform modification can include a spike in the waveform corresponding to the input current. As used herein, the term “spike” can, for example, refer to a sharp point defined by a sharp rise and sharp fall of the waveform at a position of the cycle of a waveform. For example, the spike in the waveform may be located at a maximum amplitude of the cycle of the waveform, or at a point between the maximum and zero amplitudes of the cycle of the waveform.

Although the controller 110 of the power supply 106 of the computing device 108 is described above as modifying a waveform to include a non-cyclical irregular waveform modification including a notch, a skipped half-cycle, or a spike, examples of the disclosure are not so limited. For example, the non-cyclical irregular waveform modification may include any combination thereof. The combination of the notch, the skipped half-cycle, and/or the spike modification can be intra-cycle.

The controller 104 of PDU 102 can receive the waveform that includes the non-cyclical irregular waveform modification from the power supply 106 of the computing device 108. For example, controller 110-2 of power supply 106-2 can generate the modified waveform that includes the non-cyclical irregular waveform modification can send the modified waveform to controller 104 of PDU 102.

The non-cyclical irregular modification to the waveform can correspond to a predetermined logic state. As used herein, the term “logic state” can, for example, refer to a finite amount of states that a digital signal can inhabit. For example, the logic state can include 2-level logic such as binary logic. As used herein, the term “binary logic” can, for example, refer to a number expressed in a binary numeral system or base-2 numeral system which can represent numeric values using two different symbols. The symbols can, for example, include 0 (zero) to represent logic low, and 1 (one) to represent logic high.

For instance, the non-cyclical irregular modification to the waveform can correspond to a logic high or logic low state. As an example, an intra-cycle notch located in the first half-cycle of the waveform corresponding to the input current can represent a logic high state, among other intra-cycle modifications to the waveform corresponding to the input current. In some examples, a skipped half-cycle of the waveform corresponding to the input current can represent a logic low state, among other intra-cycle modifications to the waveform corresponding to the input current. A sequence of non-cyclical irregular waveform modifications in the waveform corresponding to the input current can comprise a binary message that can include information about a computing device 108, as is further described herein.

Controller 104 of PDU 102 can analyze the modified waveform of the input current to determine a binary message included in the modified waveform. For example, the modified waveform can be analyzed by controller 104 to determine a logic state corresponding to a non-cyclical irregular modification included in the waveform.

Analyzing the modified waveform can include comparing the modified waveform to a predetermined waveform to determine the logic state corresponding to the non-cyclical irregular modification. For example, the controller 104 can determine that the modified waveform includes an intra-cycle notch located in the first half-cycle of the waveform corresponding to the input current. Controller 104 can compare the intra-cycle notch located in the first half-cycle of the waveform corresponding to the input current to a predetermined waveform indicating that an intra-cycle notch located in the first half-cycle of the waveform corresponds to a logic high state. Based on this analysis, controller 104 can determine that the intra-cycle notch located in the first half-cycle of the waveform corresponding to the input current corresponds to a logic high state.

In some examples, controller 104 can determine that the modified waveform includes intra-cycle modifications over a series of cycles of the waveform. For instance, controller 104 can determine that the modified waveform includes one skipped half-cycle followed by three full cycles followed by another skipped half-cycle.

Controller 104 can compare the one skipped half-cycle followed by three full cycles followed by another skipped half-cycle included in the modified waveform to a predetermined waveform indicating that one skipped half-cycle followed by three full cycles followed by another skipped half-cycle represents a logic low state. Based on this analysis, controller 104 can determine that the waveform modifications correspond to a logic low state.

Although the intra-cycle modifications over a series of cycles is described above as being a combination of skipped half-cycles, examples of the disclosure are not so limited. For example, the intra-cycle modifications over the series of cycles can include a combination of notches, skipped half-cycles, and/or spikes, among other non-cyclical irregular modifications or combinations of non-cyclical irregular modifications to the waveform from the power supply 106 of the computing device 108.

Controller 104 of PDU 102 can repeat the analysis of the modified waveform to compare each intra-cycle non-cyclical irregular modification or a plurality of non-cyclical irregular modifications of the modified waveform to a plurality of predetermined waveforms. For example, the controller 110-3 of power supply 106-3 of computing device 108-2 can generate a series of intra-cycle non-cyclical irregular modifications of a modified waveform to encode a series of logic states into the waveform corresponding to the input current.

Based on the comparison of each intra-cycle non-cyclical irregular modification of the plurality of non-cyclical irregular modifications of the modified waveform to the plurality of predetermined waveforms, the controller 104 of PDU 102 can determine a plurality of logic states. For example, the controller 104 can compare the plurality of non-cyclical irregular modifications of the modified waveform to the plurality of predetermined waveforms to determine that an intra-cycle notch located in the first half-cycle of the waveform corresponding to the input current can represent a logic high state, one skipped half-cycle followed by three full cycles followed by another skipped half-cycle represents a logic low state, etc., to determine the plurality of logic states.

The plurality of logic states can comprise a binary message, which can be decoded by controller 104. For example, continuing with the example from above, the controller 104 can repeatedly compare plurality of non-cyclical irregular modifications of the modified waveform to the plurality of predetermined waveforms to determine a plurality of logic states that comprise a binary message.

Controller 104 of PDU 102 can determine, based on the binary message, information about computing device 108. For example, information about the computing device 108 can include a serial number of computing device 108 and/or a serial number of power supply 106, a bay in which power supply 106 of computing device 108 is located, a computing load of computing device 108, and/or whether a redundancy of power supplies 106 is present, etc.

In some examples, controller 104 of PDU 102 can determine which power supply 106 controller 104 is communicating with based on the binary message. For example, controller 104 can determine that power supply 106-1 is located in a first bay of computing device 108-1 and that power supply 106-2 is located in a second bay of computing device 108-1 in a multi-slot computing device chassis. The controller 104 can generate a unique identifier for each of power supply 106-1 and power supply 106-2. The controller 104 can determine which output of the PDU 102 each power supply 106 is connected to. In this manner, controller 104 of PDU 102 can map the system of power supplies 106 and computing devices 108 using the unique identifier of each power supply 106 connected to a particular output of PDU 102.

In some examples, controller 104 of PDU 102 can cause a computing device load to be decreased in order to bring power consumption of the computing device 108 below a threshold level. For example, based on the binary message, the controller 104 of PDU 102 can determine which power supply 106 the PDU 102 is communicating with, and determine the computing device load is causing power consumption of the computing device 108 to be above a threshold level. For instance, the PDU 104 may determine that the computing device load of computing device 108 may be causing the computing device 108 to be consuming 15 kilowatts (kW), whereas the PDU 102 has a threshold of 12 kW. Based on the determination, the controller 104 of PDU 102 can cause computing device 108 to reduce the load of computing device such that the power consumption of computing device 108 is reduced to or below 12 kW.

In some examples, a load on a power supply 106 may be too low to cause a controller 110 of the power supply 106 to modify the waveform corresponding to the input current with a non-cyclical irregular waveform modification. In such examples, controller 104 of PDU 102 can cause the load on the power supply 106 to increase to modify the waveform with a non-cyclical irregular waveform modification by various mechanisms, including overcharging an output from PDU 102 to power supply 106 to increase current, causing computing device 108 to increase a load on power supply 106 to increase current, cause a fan speed on the power supply 106 to increase, operate output converters of power supply 106 in an inefficient manner, among other mechanisms and/or combinations thereof.

Controller 104 of PDU 102 can request a handshake signal from computing device 108 through power supply 106. As used herein, the term “handshake signal” can, for example, refer to a signal which can cause an exchange of signals between devices. In other words, a handshake can be a technique of communication between devices. For example, controller 104 of PDU 102 can request a handshake such that controller 104 of PDU 102 can exchange signals with power supply 106 of computing device 108.

The controller 104 of PDU 102 can receive a response signal from the power supply 106 in response to the handshake signal request. The response signal can include modified power factor correction characteristics. Modified power factor correction characteristics can include a modulated power factor correction and/or modified power factor correction harmonics, among other power factor correction characteristics.

The controller 110 of power supply 106 can modify the power factor correction characteristics. For example, controller 110-3 of power supply 106-3 can modify the input current to power supply 106-3 in order to modify power factor correction levels for computing device 108-2. The controller 110 of power supply 106 can modify the power factor correction levels by modulating the power factor correction and/or modifying the power factor correction harmonics, as is further described herein.

In some examples, the controller 110 of power supply 106 can modify the power factor correction levels by modulating the power factor correction of power supply 106. Modulating the power factor correction can include iteratively modulating the power factor correction of power supply 106 between a first power factor correction level and a second power factor correction level. The power factor correction can be modulated for a predetermined sequence of modulation. For example, controller 110-2 of power supply 106-2 can modulate the power factor correction of power supply 106-2 between 0.95 and 0.8, among other levels of power factor correction modulation.

The predetermined sequence of modulation can be a predetermined amount of modulations or for a predetermined period of time. In some examples, controller 110-2 of power supply 106-2 can modulate the power factor correction of power supply 106-2 between 0.95 and 0.8 ten times, although examples of the disclosure are not limited to ten times (e.g., controller 110-2 of power supply 106-2 can modulate the power factor correction of power supply 106-2 between 0.95 and 0.8 more than ten times or fewer than ten times). In some examples, controller 110-2 of power supply 106-2 can modulate the power factor correction of power supply 106-2 between 0.95 and 0.8 for five seconds, although examples of the disclosure are not limited to five seconds (e.g., controller 110-2 of power supply 106-2 can modulate the power factor correction of power supply 106-2 between 0.95 and 0.8 for more than five seconds or less than five seconds).

In some examples, the controller 110 of power supply 106 can modify the power factor correction levels by modifying the power factor correction harmonics. As used herein, the term “harmonic” can, for example, refer to a waveform with a frequency that is an integer multiple of a fundamental frequency of a waveform. Modifying the power factor correction harmonics can include iteratively modifying a current of the waveform corresponding to the input current of the power supply 106 such that the waveform iterates between a first amplitude and a second amplitude on a specific harmonic, between a first amplitude and a second amplitude on a different harmonic, etc. The power factor correction harmonics can be iteratively modified for a predetermined sequence of modification. For example, controller 110-2 of power supply 106-2 can iteratively modify the current of the waveform corresponding to the input current of the power supply 106 such that the waveform iterates between 1 ampere (amp) of third harmonic and less than 250 milliamperes (mA) of third harmonic, among other frequencies.

The predetermined sequence of modification can be a predetermined amount of modifications or for a predetermined period of time. In some examples, controller 110-2 of power supply 106-2 can iteratively modify the current of the waveform corresponding to the input current of the power supply 106 such that the waveform iterates the third harmonic between two levels ten times, although examples of the disclosure are not limited to ten times (e.g., controller 110-2 of power supply 106-2 can cause the waveform to iterate between the third harmonic between two levels more than ten times or fewer than ten times). In some examples, controller 110-2 of power supply 106-2 can iteratively modify the current of the waveform corresponding to the input current of the power supply 106 such that the third harmonic iterates between two levels for five seconds, although examples of the disclosure are not limited to five seconds (e.g., controller 110-2 of power supply 106-2 can cause the waveform to iterate the third harmonic between two levels for more than five seconds or less than five seconds). Controller 104 of PDU 102 can compare the modified power factor correction characteristics to a predetermined power factor correction characteristic.

In some examples, controller 104 can compare the modulated power factor correction of power supply 106 to a predetermined modulated power factor correction. For instance, the modulated power factor correction of power supply 106 can be modulated between 0.95 and 0.8. Controller 104 can compare the modulated power factor correction of power supply 106 to determine that it matches a predetermined modulated power factor correction being modulated between 0.95 and 0.8. Controller 104 can determine information about the computing device 108 in response to the modulated power factor correction matching the predetermined power factor correction characteristic, as is further described herein.

In some examples, controller 104 can compare the modified power factor correction harmonics to a predetermined power factor correction harmonic. For instance, the modified power factor correction harmonics can include a waveform corresponding to the input current of the power supply 106 such that the waveform iterates the third harmonic between two amplitudes. Controller 104 can compare the modified power factor correction harmonics of power supply 106 to determine that it matches a predetermined modified power factor correction harmonics including a waveform that iterates the third harmonic between two amplitudes. Controller 104 can determine information about the computing device 108 in response to the modified power factor correction harmonics matching the predetermined power factor correction characteristic, as is further described herein.

Controller 104 of PDU 102 can determine, based on the modified power factor correction characteristics, information about the computing device 108. Information about the computing device 108 can include information about the power supply 106. Controller 104 can determine the information about the computing device 108 and/or the information about the power supply 106 based on the modified power factor correction characteristics matching the predetermined power factor correction characteristic, as is further described herein.

Information about the computing device 108 and/or the power supply 106 can include a serial number of computing device 108 and/or a serial number of power supply 106, a bay in which power supply 106 of computing device 108 is located, a computing load of computing device 108, and/or whether a redundancy of power supplies 106 is present, etc., as described above.

In some examples, controller 104 of PDU 102 can determine which power supply 106 controller 104 is communicating with based on the modified power factor correction characteristics matching the predetermined power factor correction characteristic. For example, controller 104 can determine that power supply 106-1 is located in a first bay of computing device 108-1 and that power supply 106-2 is located in a second bay of computing device 108-1 in a multi-slot computing device chassis. The controller 104 can generate a unique identifier for each of power supply 106-1 and power supply 106-2. The controller 104 can determine which output of the PDU 102 each power supply 106 is connected to. In this manner, controller 104 of PDU 102 can map the system of power supplies 106 and computing devices 108 using the unique identifier of each power supply 106 connected to a particular output of PDU 102.

In some examples, controller 104 of PDU 102 can cause a computing device load to be decreased in order to bring power consumption of the computing device 108 below a threshold level. For example, based on the modified power factor correction characteristics, the controller 104 of PDU 102 can determine which of the power supplies 106 the PDU 102 is communicating with. The controller 104 of PDU 102 can determine computing loads of each of computing devices 108.

Based on the computing loads of each computing device 108, the controller 104 of PDU 102 can determine the power level of all of computing devices 108 connected to PDU 102. In some examples, the power level of all of computing devices 108 can be above a threshold level, and in response, controller 104 of PDU 102 can cause a computing device load to be decreased.

In some examples, system 100 can have twelve computing devices 108 with a total power rated from PDU 102 of 10 kilowatts (kW). If eleven computing devices 108 are at 800 watts (W) and the twelfth computing device 108 wants 1200 W, the twelfth computing device 108 may have its computing device load and keep the total power of PDU 102 at or below 10 kW.

In some examples, controller 104 can monitor the load of PDU 102 and decrease a computing device load of a computing device 108 in response to the total load of PDU 102 going above a threshold (e.g., 10 kW). For example, in an instance which the total load of PDU 102 goes above 10 kW, controller 104 can communicate with one of twelve computing devices 108 to cause one of the computing devices 108 to reduce power consumption to cause the load of PDU 102 to go below 10 kW.

Determining computing device information according to the disclosure can allow a PDU to map the system architecture of the power supplies connected to the PDU. The architecture of the system can provide insight on whether the power supplies and/or computing devices are wired correctly and/or whether power supply redundancy exists. Communication between power supplies and the PDU can be facilitated without cost and/or space prohibitive line cords and/or connectors between the power supplies and the PDU.

FIG. 2A illustrates an example of a modified waveform 212 consistent with the disclosure. Modified waveform 212 can include waveform 214, waveform cycle 216, and notch 218.

As discussed in connection with FIG. 1, waveform 214 can be a shape and form of a signal including periodic oscillations of amplitude. Waveform 214 can include waveform cycle 216. Waveform cycle 216 can include a rise in waveform 214 from a zero level to a maximum amplitude (e.g., near the top of the graph as illustrated in FIG. 2A), the return of waveform 214 to its zero level, its fall to a minimum level (e.g., near the bottom of the graph as illustrated in FIG. 2A), and its return to the zero level in a given interval.

As illustrated in FIG. 2A, the waveform 214 can include a non-cyclical irregular waveform modification. Waveform 214 can be modified by a power factor controller of a power supply of a computing device. The modification can be notch 218. The notch included in waveform 214 can correspond to a dip in output voltage of the power factor correction converter in the power supply.

As illustrated in FIG. 2A, notch 218 can be located on a first half of waveform cycle 216, although examples of the disclosure are not so limited. For example, the notch can be located on a second half of waveform cycle 216.

Notch 218 can be an intra-cycle non-cyclical irregular waveform modification. In other words, notch 218 can be located within waveform cycle 216.

FIG. 2B illustrates an example of a modified waveform 220 consistent with the disclosure. Modified waveform 220 can include waveform 221, waveform cycle 222-1, 222-2, and skipped half-cycle 224.

As illustrated in FIG. 2B, the waveform 221 can include two cycles 222-1, 222-2. Cycle 222-2 of waveform 221 can include a non-cyclical irregular waveform modification. Waveform 221 can be modified by a power factor controller of a power supply of a computing device. The modification can be skipped half-cycle 224. The skipped half-cycle 224 can correspond to a dip in output voltage of the power factor correction converter in the power supply.

As illustrated in FIG. 2B, skipped half-cycle 224 can be a half-cycle of cycle 222-2 that was skipped by the power factor controller of the power supply. The skipped half-cycle 224 can be the first half of cycle 222-2, although examples of the disclosure are not so limited. For example, the skipped half-cycle can be a second half of cycle 222-2, either halves of cycle 222-1, or any other half-cycles of waveform 221.

Skipped half-cycle 224 can be an intra-cycle non-cyclical irregular waveform modification. In other words, skipped half-cycle 224 can be located within waveform cycle 222-2.

FIG. 2C illustrates an example of a modified waveform 226 consistent with the disclosure. Modified waveform 226 can include waveform 228, half-cycle 230, and spike 232.

As illustrated in FIG. 2C, the waveform 228 can include half-cycle 230. Half-cycle 230 can be half of a full waveform cycle. Half-cycle 230 can include a non-cyclical irregular waveform modification. Waveform 228 can be modified by a power factor controller of a power supply of a computing device. The modification can be spike 232. The spike 232 can correspond to a temporary increase in output voltage of the power factor correction converter in the power supply.

As illustrated in FIG. 2C, spike 232 can be located on a first half-cycle 230 of a full waveform cycle, although examples of the disclosure are not so limited. For example, the spike can be located on a second half of a full waveform cycle.

Spike 232 can be an intra-cycle non-cyclical irregular waveform modification. In other words, spike 232 can be located within a waveform cycle (e.g., within half-cycle 230).

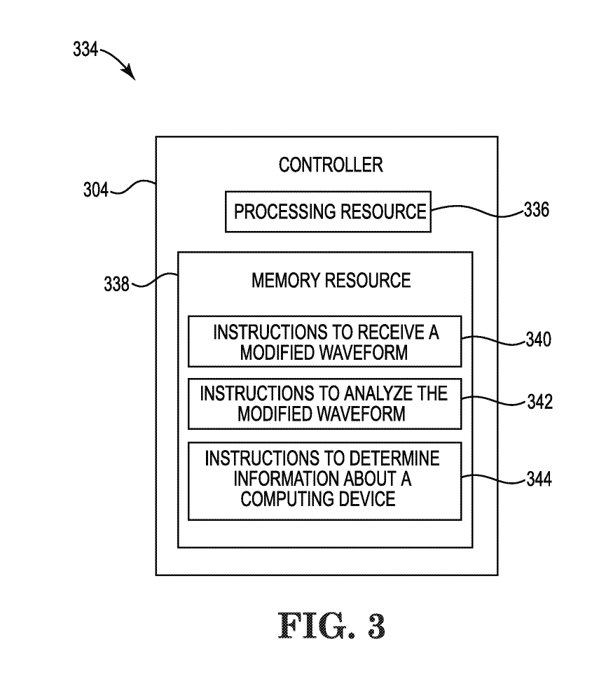

FIG. 3 is a diagram 334 of an example controller 304 to determine computing device information consistent with the disclosure. As described herein, the controller 304 (e.g., controller 104, described in connection with FIG. 1) may perform a function related to determining computing device information. Although not illustrated in FIG. 3, the controller 304 may include a machine-readable storage medium. Although the following descriptions refer to an individual processing resource and an individual machine-readable storage medium, the descriptions may also apply to a system with multiple processing resources and multiple machine-readable storage mediums. In such examples, the controller 304 may be distributed across multiple machine-readable storage mediums and the controller 304 may be distributed across multiple processing resources. Put another way, the instructions executed by the controller 304 may be stored across multiple machine-readable storage mediums and executed across multiple processing resources, such as in a distributed or virtual computing environment.

As illustrated in FIG. 3, the controller 304 may comprise a processing resource 336, and a memory resource 338 storing machine-readable instructions to cause the processing resource 336 to perform an operation relating to determining computing device information. That is, using the processing resource 336 and the memory resource 338, the controller 304 may determine information about a computing device based on a binary message, among other operations. Processing resource 336 may be a central processing unit (CPU), microprocessor, and/or other hardware device suitable for retrieval and execution of instructions stored in memory resource 338.

The controller 304 may include instructions 340 stored in the memory resource 338 and executable by the processing resource 336 to receive a modified waveform. For example, controller 304 may include instructions 340 stored in the memory resource 338 and executable by the processing resource 336 to receive a waveform corresponding to an input current that includes a non-cyclical irregular waveform modification from a power supply of a computing device.

The controller 304 may include instructions 342 stored in the memory resource 338 and executable by the processing resource 336 to analyze the modified waveform. For example, controller 304 may include instructions 342 stored in the memory resource 338 and executable by the processing resource 336 to analyze the modified waveform of the input current to determine a binary message included in the modified waveform.

The controller 304 may include instructions 344 stored in the memory resource 338 and executable by the processing resource 336 to determine information about a computing device. For example, controller 304 may include instructions 344 stored in the memory resource 338 and executable by the processing resource 336 to determine, based on the binary message, information about the computing device.

In this manner, the controller 304 may determine information about a computing device. Computing device information can allow a PDU to map system architecture of power supplies connected to the PDU, where the system architecture can provide insight on wiring connections and/or redundancy of power supplies connected to the PDU.

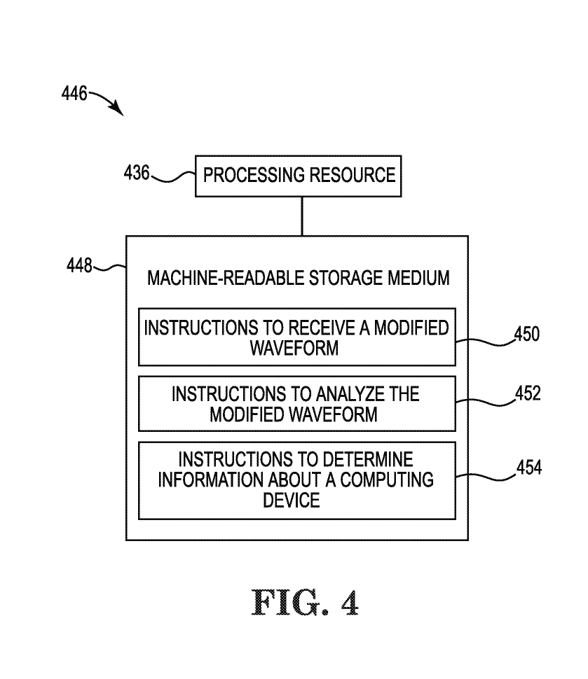

FIG. 4 is a block diagram of an example of a system 446 consistent with the disclosure. In the example of FIG. 4, system 446 includes a processing resource 436 (e.g., processing resource 336, described in connection with FIG. 3) and a machine-readable storage medium 448. Although the following descriptions refer to an individual processing resource and an individual machine-readable storage medium, the descriptions may also apply to a system with multiple processing resources and multiple machine-readable storage mediums. In such examples, the instructions may be distributed across multiple machine-readable storage mediums and the instructions may be distributed across multiple processing resources. Put another way, the instructions may be stored across multiple machine-readable storage mediums and executed across multiple processing resources, such as in a distributed computing environment.

Processing resource 436 may be a central processing unit (CPU), microprocessor, and/or other hardware device suitable for retrieval and execution of instructions stored in machine-readable storage medium 448. In the particular example shown in FIG. 4, processing resource 436 may receive, determine, and send instructions 450, 452, 454. As an alternative or in addition to retrieving and executing instructions, processing resource 436 may include an electronic circuit comprising an electronic component for performing the operations of the instructions in machine-readable storage medium 448. With respect to the executable instruction representations or boxes described and shown herein, it should be understood that part or all of the executable instructions and/or electronic circuits included within one box may be included in a different box shown in the figures or in a different box not shown.

Machine-readable storage medium 448 may be any electronic, magnetic, optical, or other physical storage device that stores executable instructions. Thus, machine-readable storage medium 448 may be, for example, Random Access Memory (RAM), an Electrically-Erasable Programmable Read-Only Memory (EEPROM), a storage drive, an optical disc, and the like. The executable instructions may be “installed” on the system 446 illustrated in FIG. 4. Machine-readable storage medium 448 may be a portable, external or remote storage medium, for example, that allows the system 446 to download the instructions from the portable/external/remote storage medium. In this situation, the executable instructions may be part of an “installation package”. As described herein, machine-readable storage medium 448 may be encoded with executable instructions related to determining computing device information.

Instructions to receive a modified waveform 450, when executed by processing resource 436, may cause system 446 to receive a waveform corresponding to an input current that includes a non-cyclical irregular modification to the waveform from a power supply of a computing device. The non-cyclical irregular modification to the waveform can be an intra-cycle waveform modification.

Instructions to analyze the modified waveform 452, when executed by processing resource 436, may cause system 446 to analyze the modified waveform of the input current to determine a binary message included in the modified waveform.

Instructions to determine information about a computing device 454, when executed by processing resource 436, may cause system 446 to determine, based on the binary message, information about the computing device. Information about the computing device can include information about a power supply of the computing device, and can include a serial number of the computing device and/or a serial number of power supply, a bay in which the power supply of the computing device is located, a computing load of computing device, and/or whether a redundancy of power supplies is present, etc.

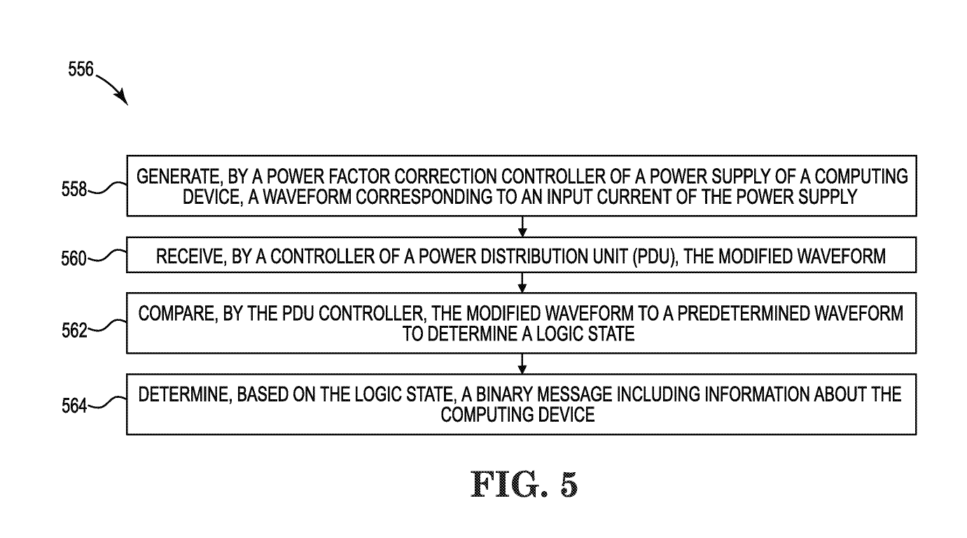

FIG. 5 illustrates an example of a method 556 consistent with the disclosure. Method 556 may be performed by a controller of a power distribution unit (e.g., controller 104, described in connection with FIG. 1) and a controller of a power supply (e.g., controller 110, described in connection with FIG. 1).

At 558, the method 556 may include generating, by a power factor correction controller of a power supply of a computing device, a waveform corresponding to an input current of the power supply. The waveform can be modified by the power factor correction controller. For example, the power factor correction controller can include an intra-cycle non-cyclical irregular modification to the waveform. The intra-cycle modifications can include a combination of notches, skipped half-cycles, and/or spikes, over a series of waveform cycles, among other non-cyclical irregular modifications or combinations of non-cyclical irregular modifications to the waveform.

At 560, the method 556 may include receiving, by a controller of a PDU, the modified waveform.

At 562, the method 556 may include comparing, by the PDU controller, the modified waveform to a predetermined waveform to determine a logic state. The logic state can correspond to the intra-cycle non-cyclical irregular waveform modification. For example, a first intra-cycle non-cyclical irregular waveform modification can correspond to a logic low state which may be represented by a zero, and a second intra-cycle non-cyclical irregular waveform modification can correspond to a logic high state which may be represented by a one.

At 564, the method 556 may include determining, based on the logic state, a binary message including information about the computing device. For example, the series of ones and zeros represented by the series of logic states from the intra-cycle non-cyclical irregular waveform modifications can comprise a binary message, which can include information about the computing device.

Method 556 may be repeated to compare each intra-cycle non-cyclical irregular waveform modification of a plurality of non-cyclical irregular waveform modifications of the modified waveform to a plurality of predetermined waveforms. Based on the comparison, the PDU controller can determine a plurality of logic states. As described above, the plurality of logic states can comprise a series of logic states. The PDU controller can determine a binary message based on the plurality of logic states.

Method 556 may be repeated multiple times to ensure redundancy. For example, if an error in waveform modification occurs by the power factor correction controller in modifying the waveform, an incorrect binary message may be determined by the PDU controller. The power factor correction controller may modify the waveform multiple times, and the PDU controller may determine a binary message multiple times, in order to ensure the PDU controller has correctly determined the binary message.

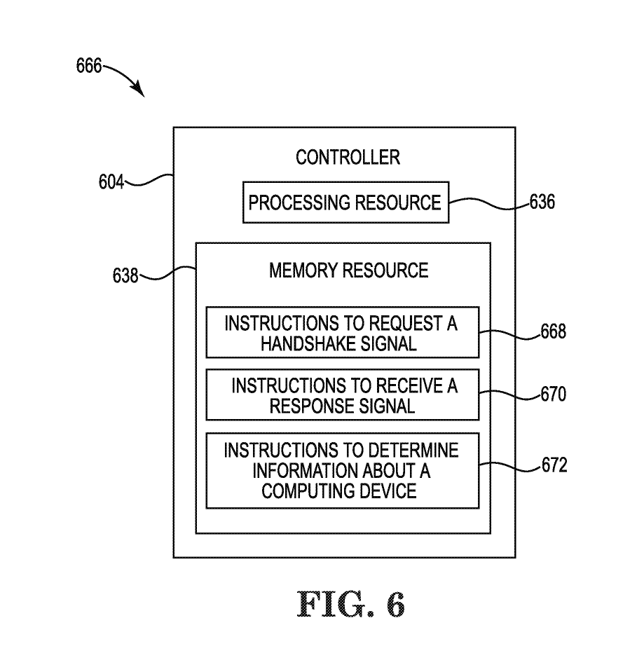

FIG. 6 is a diagram 666 of an example controller 604 to determine computing device information consistent with the disclosure. As illustrated in FIG. 6, controller 604 (e.g., controller 304, described in connection with FIG. 3) may comprise a processing resource 636 (e.g., processing resource 336, described in connection with FIG. 3) and a memory resource 638 (e.g., memory resource 338, described in connection with FIG. 3).

The controller 604 may include instructions 668 stored in the memory resource 638 and executable by the processing resource 636 to request a handshake signal. Controller 604 can request a handshake signal from a power supply of a computing device.

The controller 604 may include instructions 670 stored in the memory resource 638 and executable by the processing resource 636 to receive a response signal. The response signal can be received from the power supply, where the response signal can include modified power factor correction characteristics in response to the handshake signal request. Modified power factor correction characteristics can include a modulated power factor correction and/or modified power factor correction harmonics, among other power factor correction characteristics.

The controller 604 may include instructions 672 stored in the memory resource 638 and executable by the processing resource 636 to determine information about a computing device. The information about the computing device can be determined by controller 604 based on the modified power factor correction characteristics. Computing device information can allow a PDU to map system architecture of power supplies connected to the PDU, where the system architecture can provide insight on wiring connections and/or redundancy of power supplies connected to the PDU.

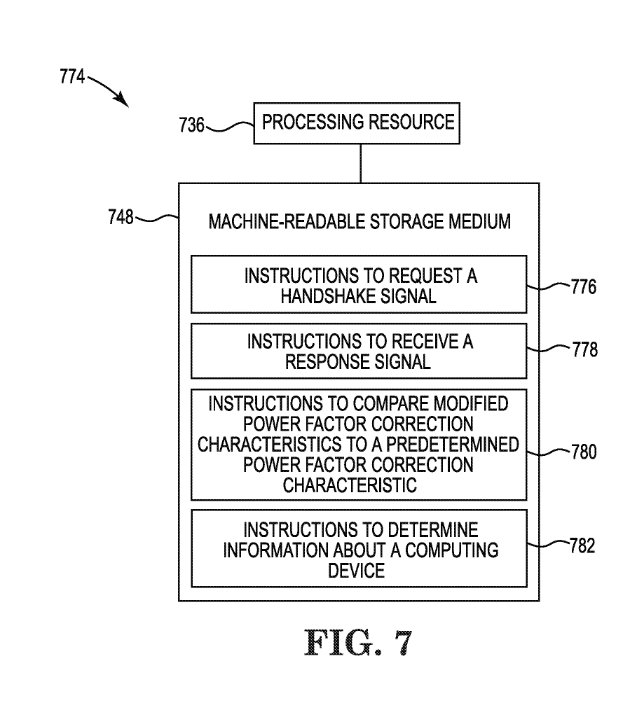

FIG. 7 is a block diagram of an example of a system 774 consistent with the disclosure. In the example of FIG. 7, system 774 includes a processing resource 736 (e.g., processing resource 336, 636, described in connection with FIGS. 3 and 6, respectively) and a machine-readable storage medium 748 (e.g., machine-readable storage medium 448, described in connection with FIG. 4).

Instructions to request a handshake signal 776, when executed by processing resource 736, may cause system 774 to request a handshake signal from a power supply of a computing device.

Instructions to receive a response signal 778, when executed by processing resource 736, may cause system 774 to receive a response signal. The response signal can be received by the system 774 from the power supply, where the response signal can include modified power factor correction characteristics in response to the handshake signal request. Modified power factor correction characteristics can include a modulated power factor correction and/or modified power factor correction harmonics, among other power factor correction characteristics.

Instructions 780, when executed by processing resource 736, may cause system 774 to compare the modified power factor correction characteristics to a predetermined power factor correction characteristic. In some examples in which the modified power factor correction characteristic includes a modulated power factor correction, system 774 can compare the modulated power factor correction of the power supply with a predetermined modulated power factor correction. In some examples in which the modified power factor correction characteristic includes modified power factor correction harmonics, system 774 can compare the modified power factor correction harmonics to a predetermined power factor correction harmonic.

Instructions 782, when executed by processing resource 736, may cause system 774 to determine information about a computing device. Information about the computing device can be determined based on the comparison of the modified power factor correction characteristics to a predetermined power factor correction characteristic. Information about the computing device can include information about a power supply of the computing device, and can include a serial number of the computing device and/or a serial number of power supply, a bay in which the power supply of the computing device is located, a computing load of computing device, and/or whether a redundancy of power supplies is present, etc.

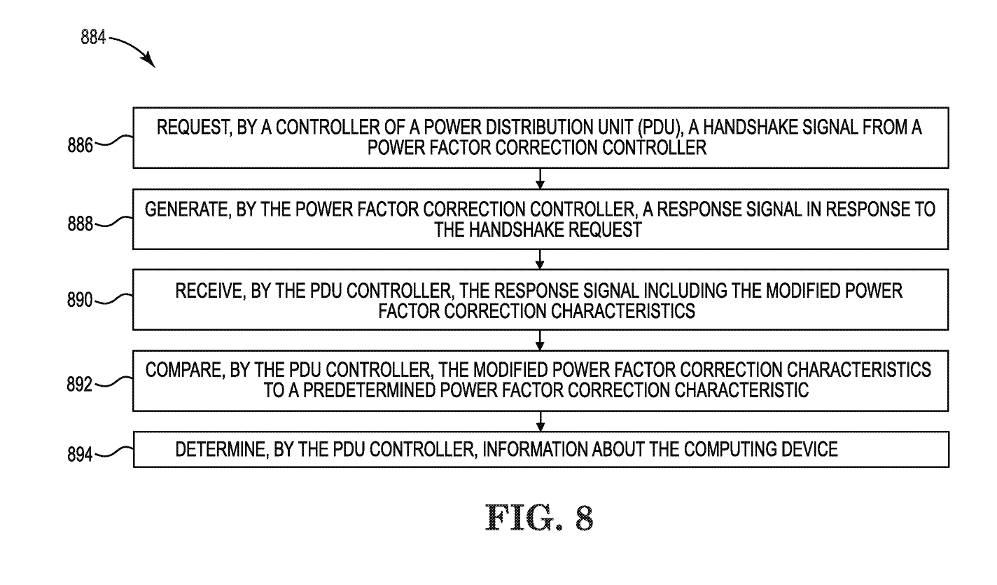

FIG. 8 illustrates an example of a method 884 consistent with the disclosure. Method 884 may be performed by a controller of a power distribution unit (e.g., controller 104, described in connection with FIG. 1) and a controller of a power supply (e.g., controller 110, described in connection with FIG. 1).

At 886, the method 884 may include requesting, by a controller of a PDU, a handshake signal from a power factor correction controller. The power factor correction controller can be a controller included in a power supply of a computing device.

At 888, the method 884 may include generating, by the power factor correction controller, a response signal in response to the handshake request. The response signal can include modified power factor correction characteristics. For example, modified power factor correction characteristics may include a modulated power factor correction and/or modified power factor correction harmonics, among other power factor correction characteristics.

In some examples, the power factor correction controller can generate the modulated power factor correction. For example, the power factor correction controller can iteratively modulate the power factor correction of the power supply between a first power factor correction level and a second power factor correction level. The power factor correction controller can iteratively modulate the power factor correction for a predetermined sequence of modulation.

In some examples, the power factor correction controller can generate the modified power factor correction harmonics. For example, the power factor correction controller can iteratively modify a current of a waveform corresponding to an input current of the power supply such that the waveform harmonics iterates between a first level and a second level. The power factor correction controller can iteratively modify the power factor correction harmonics for a predetermined sequence of modification.

At 890, the method 884 may include receiving, by the PDU controller, the response signal including the modified power factor correction characteristics. The response signal may be received by the PDU controller from the power factor correction controller.

At 892, the method 884 may include comparing, by the PDU controller, the response signal including the modified power factor correction characteristics to a predetermined power factor correction characteristic. The PDU controller can utilize a current sensor to monitor a current and/or a voltage from the power supply of the computing device, and compare the current and/or the voltage to a reference current and/or reference voltage.

At 894, the method 884 may include determining, by the PDU controller, information about the computing device. The PDU controller can determine information about the computing device in response to the modified power factor correction characteristics matching the predetermined power factor correction characteristics.

In the foregoing detailed description of the disclosure, reference is made to the accompanying drawings that form a part hereof, and in which is shown by way of illustration how examples of the disclosure may be practiced. These examples are described in sufficient detail to enable those of ordinary skill in the art to practice the examples of this disclosure, and it is to be understood that other examples may be utilized and that process, electrical, and/or structural changes may be made without departing from the scope of the disclosure.

The figures herein follow a numbering convention in which the first digit corresponds to the drawing figure number and the remaining digits identify an element or component in the drawing. Similar elements or components between different figures may be identified by the use of similar digits. For example, 104 may reference element “04” in FIG. 1, and a similar element may be referenced as 304 in FIG. 3. Elements shown in the various figures herein can be added, exchanged, and/or eliminated so as to provide a plurality of additional examples of the disclosure. In addition, the proportion and the relative scale of the elements provided in the figures are intended to illustrate the examples of the disclosure, and should not be taken in a limiting sense. As used herein, the designators “M” and “N”, particularly with respect to reference numerals in the drawings, indicates that a plurality of the particular feature so designated can be included with examples of the disclosure. The designators can represent the same or different numbers of the particular features. Further, as used herein, “a plurality of” an element and/or feature can refer to more than one of such elements and/or features.

What is claimed:

1. A controller, comprising:
a processing resource; and
a memory resource storing machine-readable instructions to cause the processing resource to:
request a handshake signal from a power supply of a computing device;
receive a response signal from the power supply that includes modified power factor correction characteristics in response to the handshake signal request; and
determine, based on the modified power factor correction characteristics, information about the computing device.

2. The controller of claim 1, including instructions to cause the processing resource to compare the modified power factor correction characteristics to a predetermined power factor correction characteristic.

3. The controller of claim 2, including instructions to determine the information about the computing device based on the modified power factor correction characteristics matching the predetermined power factor correction characteristic.

4. The controller of claim 1, wherein the modified power factor correction characteristics include a modulated power factor correction.

5. The controller of claim 1, wherein the modified power factor correction characteristics include modified power factor correction harmonics.

6. The controller of claim 1, wherein the instructions to determine information about the computing device include instructions to cause the processing resource to determine information about the power supply of the computing device.

7. The controller of claim 1, wherein the controller is included in a power distribution unit.

8. A non-transitory machine-readable storage medium having stored thereon machine-readable instructions to cause a computer processor to:
request a handshake signal from a power supply of a computing device;
receive a response signal from the power supply that includes modified power factor correction characteristics in response to the handshake signal request;
compare the modified power factor correction characteristics to a predetermined power factor correction characteristic; and
determine, based on the comparison, information about the computing device.

9. The medium of claim 8, wherein the modified power factor correction characteristics include a modulated power factor correction, and comprising instructions to:
compare the modulated power factor correction to the predetermined power factor correction characteristic; and
determine information about the computing device in response to the modulated power factor correction matching the predetermined power factor correction characteristic.

10. The medium of claim 8, wherein the modified power factor correction characteristics include modified power factor correction harmonics, and comprising instructions to:
compare the modified power factor correction harmonics to the predetermined power factor correction characteristic; and
determine information about the computing device in response to the modified power factor correction harmonics matching the predetermined power factor correction characteristic.

11. The medium of claim 8, comprising instructions to determine, in response to the modified power factor correction characteristics matching the predetermined power factor correction characteristic, information about the computing device including at least one of:
a serial number of the computing device; and
a bay in which the power supply of the computing device is located.

12. A method, comprising:
request, by a controller of a power distribution unit (PDU), a handshake signal from a power factor correction controller of a power supply of a computing device;
generate, by the power factor correction controller, a response signal that includes modified power factor correction characteristics in response to the handshake signal request;
receive, by the PDU controller, the response signal including the modified power factor correction characteristics;
compare, by the PDU controller, the modified power factor correction characteristics to a predetermined power factor correction characteristic; and
determine, by the PDU controller in response to the modified power factor correction characteristics matching the predetermined power factor correction characteristic, information about the computing device.

13. The method of claim 12, wherein the modified power factor correction characteristics include a modulated power factor correction, and wherein the method includes generating, by the power factor correction controller, the modulated power factor correction by:
iteratively modulating the power factor correction of the power supply between a first power factor correction level and a second power factor correction level for a predetermined sequence of modulation.

14. The method of claim 12, wherein the modified power factor correction characteristics include modified power factor correction harmonics, and wherein the method includes generating, by the power factor correction controller, the modified power factor correction harmonics by:
iteratively modifying a current of a waveform corresponding to an input current of the power supply such that the waveform iterates between a first amplitude and a second amplitude of a specific harmonic during a predetermined modification sequence.

15. The method of claim 12, wherein comparing the modified power factor correction characteristics to the predetermined power factor correction characteristic includes comparing a voltage and a current of the modified power factor correction characteristics to a voltage and a current of the predetermined power factor correction characteristic.
